(19) United States
(12) Patent Application Publication
(10) Pub. No.: US 2025/0393367 A1
(43) Pub. Date: Dec. 25, 2025

(54) DISPLAY PANEL AND DISPLAY DEVICE

(71) Applicant: Tianma Advanced Display Technology Institute (Xiamen) Co., Ltd., Xiamen (CN)

(72) Inventors: Zhenyu Jia, Xiamen (CN); Min Ming, Xiamen (CN); Kerui Xi, Xiamen (CN); Yingteng Zhai, Xiamen (CN); Bo Yang, Xiamen (CN)

(73) Assignee: Tianma Advanced Display Technology Institute (Xiamen) Co., Ltd., (omitted)

(21) Appl. No.: 19/247,823

(22) Filed: Jun. 24, 2025

(30) Foreign Application Priority Data
Mar. 3, 2025 (CN) 202510244968.7

(51) Int. Cl. H10H 29/49

(52) U.S. Cl. CPC H10H 29/49

(57) ABSTRACT

A display panel and a display device. The display panel includes a substrate, a pixel circuit, a signal terminal, a signal bus extending in a first direction, and a connection line segment extending in a second direction. The pixel circuit, the signal terminal, the signal bus, and the connection line segment are arranged at a side of the substrate. Pixel circuits are provided in the first direction to form a pixel circuit row. Pixel circuit rows are provided in the second direction. Signal terminals are provided at a side of the pixel circuit rows in the second direction. The signal bus is arranged between two adjacent pixel circuit rows. The connection line segment has one end electrically connected to the signal bus and the other to the signal terminal. The signal bus comprises a first and a second line segments arranged in the first direction and in different layers.

### CROSS-REFERENCE TO RELATED APPLICATIONS

The present application claims priority to Chinese patent application No. 202510244968.7, filed on Mar. 3, 2025, which is hereby incorporated by reference in its entirety.

### TECHNICAL FIELD

The present disclosure relates to the field of display technologies, and in particular, to a display panel and a display device.

### BACKGROUND

In some current display technologies, in order to conduct dot-screen testing of a panel, a horizontal signal bus is arranged in a display region, and a signal is transmitted via the horizontal signal bus to activate pixels during the dot-screen testing. The horizontal signal bus runs transversely across an entire display screen, which poses a certain risk of electrostatic damage, thereby affecting the performance reliability of the display panel.

### SUMMARY

Embodiments of the present disclosure provide a display panel and a display device to solve the problem that circuits of the display panel are prone to be damaged by static electricity.

In an aspect, an embodiment of the present disclosure provides a display panel including a substrate, pixel circuits, signal terminals, a signal bus extending in a first direction, and a connection line segment extending in a second direction. The substrate, the pixel circuits, the signal terminals, the signal bus, the connection line segment are arranged at a side of the substrate. The first direction intersects with the second direction. The pixel circuits are provided in the first direction to form pixel circuit rows, and the pixel circuit rows are provided in the second direction. The signal terminals are provided at a side of the pixel circuit rows in the second direction. The signal bus is arranged between two adjacent pixel circuit rows. One end of the connection line segment is electrically connected to the signal bus, and the other end of the connection line segment is electrically connected to at least one of the signal terminals. The signal bus includes a first line segment and a second line segment that are arranged in the first direction, and the first line segment and the second line segment are arranged in different layers.

In another aspect, based on the same inventive concept, an embodiment of the present disclosure provides a display device. The display device includes a substrate; pixel circuits provided in a first direction to form pixel circuit rows arranged in a second direction; signal terminals provided at a side of the pixel circuit rows in the second direction; a signal bus extending in the first direction and arranged between two adjacent pixel circuit rows; and a connection line segment extending in the second direction. The pixel circuits, the signal terminals, the signal bus, and the connection line segment are arranged at a side of the substrate, and the first direction intersects with the second direction. One end of the connection line segment is electrically connected to the signal bus, and the other end of the connection line segment is electrically connected to at least one of the signal terminals. The signal bus includes a first line segment and a second line segment, and the first line segment and the second line segment are arranged in the first direction and in different layers.

### BRIEF DESCRIPTION OF DRAWINGS

In order to better illustrate the technical solutions in embodiments of the present disclosure or the related art, the drawings used in the description of the embodiments will be briefly illustrated as follows. It should be noted that, the drawings described below are merely some, rather than all, of the embodiments of the present disclosure. Based on these drawings, those skilled in the art can obtain other drawings without any creative effort.

FIG. 1 is a simplified schematic diagram of a display panel according to an embodiment of the present disclosure;

FIG. 2 is a schematic diagram of another display panel according to an embodiment of the present disclosure;

FIG. 3 is a partial schematic diagram of a display panel according to an embodiment of the present disclosure;

FIG. 4 is a schematic diagram of a pixel circuit according to an embodiment of the present disclosure;

FIG. 5 is a simplified schematic diagram of another display panel according to an embodiment of the present disclosure;

FIG. 6 is a structural schematic diagram of a film layer of a display panel according to an embodiment of the present disclosure;

FIG. 7 is a simplified schematic diagram of another display panel according to an embodiment of the present disclosure;

FIG. 8 is a simplified schematic diagram of another display panel according to an embodiment of the present disclosure;

FIG. 9 is a partial schematic diagram of another display panel according to an embodiment of the present disclosure;

FIG. 10 is a partial schematic diagram of another display panel according to some embodiments of the present disclosure;

FIG. 11 is an enlarged schematic diagram of a region Z shown in FIG. 3;

FIG. 12 is another enlarged schematic diagram of a region Z shown in FIG. 3;

FIG. 13 is another enlarged schematic diagram of a region Z shown in FIG. 3;

FIG. 14 is another enlarged schematic diagram of a region Z shown in FIG. 3;

FIG. 15 is another enlarged schematic diagram of a region Z shown in FIG. 3;

FIG. 16 is another enlarged schematic diagram of a region Z shown in FIG. 3;

FIG. 17 is a partial schematic diagram of another display panel according to an embodiment of the present disclosure;

FIG. 18 is a partial schematic diagram of another display panel according to an embodiment of the present disclosure;

FIG. 19 is a partial schematic diagram of another display panel according to an embodiment of the present disclosure; and

FIG. 20 is a schematic diagram of a display device according to an embodiment of the present disclosure.

### DESCRIPTION OF EMBODIMENTS

In order to more clearly illustrate objectives, technical solutions, and advantages of embodiments of the present disclosure, the technical solutions in embodiments of the present disclosure are clearly and completely described in details with reference to the drawings. It will be apparent that the described embodiments are merely some, rather than all, of the embodiments of the present disclosure. All other embodiments obtained by those skilled in the art without any creative effort based on the embodiments of the present disclosure shall fall into a scope of the present disclosure.

Terms used in the embodiments of the present disclosure are only used for the purpose of describing specific embodiments, but not intended to limit the present disclosure. Singular forms of “a/an”, “said” and “the” used in the embodiments of the present disclosure and the appended claims are also intended to include plural forms, unless explicitly indicating other meanings.

An embodiment of the present disclosure provide a display panel, which improves a structure of a horizontal bus in the display panel, to reduce a risk of electrostatic accumulation of the horizontal bus and to improve the performance reliability of the display panel. The display panel provided by the embodiments of the present disclosure can be applied to manufacture a frameless spliced display screen.

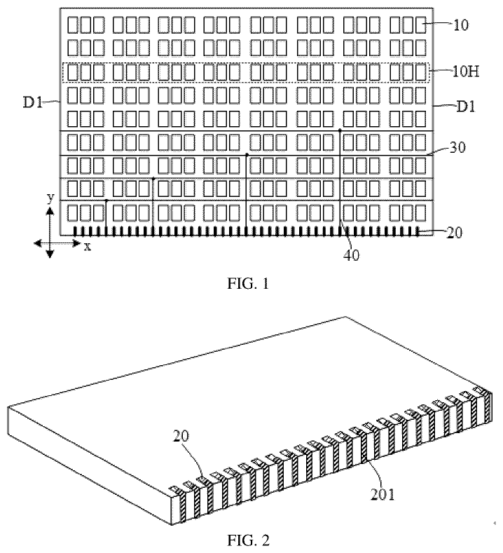

FIG. 1 is a simplified schematic diagram of a display panel according to an embodiment of the present disclosure. FIG. 2 is a schematic diagram of another display panel according to an embodiment of the present disclosure. As shown in FIG. 1, the display panel may include pixel circuits 10, signal terminals 20, a signal bus 30 extending along a first direction x, and a connection line segment 40 extending along a second direction y. The first direction x may intersect with the second direction y. The pixel circuit 10, the signal terminal 20, the signal bus 30, and the connection line segment 40 may be arranged at the same side of the substrate (not shown in FIG. 1). The pixel circuits 10 may be arranged along the first direction x to form pixel circuit rows 10H, and the pixel circuit rows 10H may be arranged along the second direction y. The signal terminals 20 may be arranged at a side of the pixel circuit 10 rows in the second direction y. Alternatively, the signal terminals 20 may be connected to a side lead of the display panel. FIG. 2 shows that the signal terminal 20 may be connected to the side leads 201 of the display panel. The side leads 201 may lead a signal to the back surface of the display panel. The side leads 201 may then be bound to a flexible circuit board, which may reduce the frame of the display panel, so as to achieve a frameless display effect. The display panel may further include a plurality of light-emitting devices, such as light-emitting diodes (LEDs). The pixel circuit 10 may be connected to the light-emitting device LED.

As shown in FIG. 1, the signal bus 30 may be arranged between two adjacent pixel circuit rows 10H. An end of the connection line segment 40 may be electrically connected to the signal bus 30, and another end of the connection line segment 40 may be electrically connected to the signal terminal 20. A signal provided by the signal terminal 20 may be introduced into the signal bus 30 through the connection line segment 40. A plurality of first signal lines (not shown in FIG. 1) extending along the second direction y may be further arranged in the display panel. The signal bus 30 may be connected to the first signal lines through a connection portion. The connection portion may be a via penetrating an insulating layer, a thin film transistor, or similar. In some embodiments of the present disclosure, the connection line segment 40 functions as a signal connection between the signal bus 30 and the signal terminal 20. In other embodiments of the present disclosure, the connection line segment 40 is a partial line segment in the first signal line extending in the second direction y, and the first signal line where the connection line segment 40 is located is further configured to transmit a signal required for driving pixels to emit light.

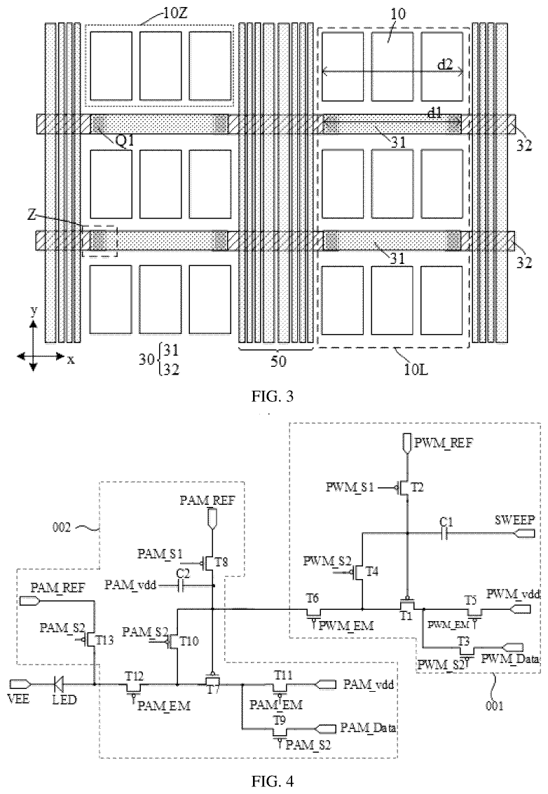

FIG. 3 is a partial schematic diagram of a display panel according to an embodiment of the present disclosure. As shown in FIG. 3, the signal bus 30 may include a first line segment 31 and a second line segment 32 that are both arranged in the first direction x. The first line segment 31 and the second line segment 32 may be arranged in different layers, and the first line segment 31 may be connected to the second line segment 32 in a first region Q1. A via may be formed in the first region Q1. The embodiment illustrated in FIG. 3 shows the position of the first region Q1, but does not show the via. Alternatively, in the extending direction of the signal bus 30, the first line segments 31 and the second line segments 32 may be arranged alternately. The illustrated embodiment further shows a plurality of first signal lines 50 extending along the second direction y. At least two pixel circuits 10 in the display panel may be arranged in the first direction x to form pixel circuit groups 10Z, and a first signal line 50 may be arranged between adjacent pixel circuit groups 10Z.

In the display panel according to the illustrated embodiment, the signal bus 30 includes a first line segment 31 and a second line segment 32 arranged in different layers, and the first line segment 31 and the second line segment 32 can be made of different materials. For example, the resistivity of the material used for the first line segment 31 may be smaller than the resistivity of the material used for the second line segment 32. Signal lines intersecting with one another in an extending direction may be arranged in the display panel, and the signal bus 30 extending in the first direction x may intersect with some signal lines (such as the first signal lines 50) extending in the second direction y. One signal bus 30 may be connected to one or more first signal lines 50, and may also cross the first signal lines 50 in an insulated manner. In an embodiment of the present disclosure, the first line segment 31 and the second line segment 32 may be arranged in different layers, thereby reducing the overall resistance of the signal bus 30, which may reduce the risk of electrostatic accumulation on the signal bus 30 and improve the performance reliability of the display panel. Moreover, the signal bus 30 may include line segments located on different metal layers. The film layer where the line segment of the signal bus 30 is located may be selected at an overlapping position of the signal bus 30 and other signal lines, and the metal layer of the display panel may enable the signal bus 30 to cross other signal lines in an insulated manner.

In an embodiment of the present disclosure, the display panel includes a plurality of signal buses 30. It should be understood that, in FIG. 1, the number of the signal buses 30 is merely illustrative. As shown in FIG. 1, the display panel may include first ends D1 extending along the second direction y. Two first ends D1 may be arranged opposite to each other. The signal bus 30 may extend to edges of the first ends D1. In other words, a side surface of the first end D1 of the display panel may expose the signal bus 30. The signal bus 30 may be configured to provide a signal, (e.g., a signal required by a shift driving circuit) during a dot-screen testing. In a manufacturing process of the display panel, an end portion of the signal bus 30 may be connected to a test pad. The test substrate arranged the side of the display panel may be cut off to form the first end D1 of the display panel after the dot-screen testing, such that the side surface of the first end D1 exposes the signal bus 30.

In an embodiment of the present disclosure, the pixel circuit 10 may be a conventional circuit 7T1C, i.e., including seven transistors and one storage capacitor. The pixel circuit 10 may also be a relatively complex pixel circuit. For example, the pixel circuit 10 may include a pulse width modulation circuit and a pulse amplitude modulation circuit.

FIG. 4 is a schematic diagram of a pixel circuit according to an embodiment of the present disclosure. As shown in FIG. 4, the pixel circuit may include a first driving circuit 001 and a second driving circuit 002. The first driving circuit 001 may be configured to control a duration of providing a driving current to a light-emitting device LED based on a first data voltage PWM-data, and the second driving circuit 002 may be configured to control an amplitude of providing the driving current to the light-emitting device LED based on a second data voltage PAM-data. The first driving circuit 001 may be a pulse width modulation circuit, and the second driving circuit 002 may be a pulse amplitude modulation circuit.

The first driving circuit 001 may include a first driving transistor T1, a first gate reset transistor T2, a first data writing transistor T3, a first compensation transistor T4, a first control transistor T6, a second control transistor T5, and a first capacitor C1. The first capacitor C1 may be a storage capacitor in the first driving circuit 001. The second control transistor T5 may be connected to and between a first power voltage PWM-vdd and a first electrode of the second driving transistor T1. The first control transistor T6 may be connected to and between a second electrode of the first driving transistor T1 and a first node N1. The first data writing transistor T3 may be connected to the first electrode of the first driving transistor T1. The first compensation transistor T4 may be connected to the second electrode of the first driving transistor T1 and a gate of the first driving transistor T1. The first gate reset transistor T2 may be connected to the gate of the first driving transistor T1. A first electrode plate of the first capacitor C1 may be connected to the gate of the first driving transistor T1. A second electrode plate of the first capacitor C1 may be connected to a swept-frequency signal SWEEP. A gate of the first gate reset transistor T2 may be connected to a scan signal PWM-S1. A gate of the first data writing transistor T3 and a gate of the first compensation transistor T4 may both be connected to a scan signal PWM-S2. A gate of the first control transistor T6 and a gate of the second control transistor T5 may both be connected to a first light-emitting control signal PWM-EM. The first gate reset transistor T2 may receive a reset signal PWM-REF.

The second driving circuit 002 may include a second driving transistor T7, a second gate reset transistor T8, a second data writing transistor T9, a second compensation transistor T10, a third control transistor T11, a fourth control transistor T12, an electrode reset transistor T13, and a second capacitor C2. The third control transistor T11 may be connected to and between the second power voltage PAM-vdd and a first electrode of the second driving transistor T7.The fourth control transistor T12 may be connected to and between a second electrode of the second driving transistor T7 and the light-emitting device LED. The second driving transistor T7 may be configured to generate a driving current under the control of a gate voltage thereof, and a gate of the second driving transistor T7 may be connected to the first node N1. The second data writing transistor T9 may be connected to the first electrode of the second driving transistor T7. The second compensation transistor T10 may be connected to the second electrode and the gate of the second driving transistor T7. The second gate reset transistor T8 may be connected to the gate of the second driving transistor T7. The electrode reset transistor T13 may be connected to a first electrode of the light-emitting device LED. The fourth control transistor T12 may be connected to the first electrode of the light-emitting device LED. A second electrode of the light-emitting device LED may be connected to a third power voltage VEE. A gate of the second gate reset transistor T8 may be connected to the scan signal PAM-S1. A gate of the second data writing transistor T9, a gate of the second compensation transistor T10 and a gate of the electrode reset transistor T13 may all be connected to the scan signal PAM-S2. A gate of the third control transistor T11 and a gate of the fourth control transistor T12 may both be connected to a second light-emitting control signal PAM-EM. The second gate reset transistor T8 and the electrode reset transistor T13 respectively may receive a reset signal PAM-REF.

FIG. 4 further shows that the electrode reset transistor T13 may receive the reset signal PAM-REF. In other embodiments of the present disclosure, the electrode reset transistor T13 receives a constant voltage signal, and the constant voltage signal and the reset signal PAM-REF have different voltage values.

Further, in some embodiments of the present disclosure, the first gate reset transistor T2, the first compensation transistor T4, the second gate reset transistor T8, and the second compensation transistor T10 shown in FIG. 4 are all dual-gate transistors.

To drive the pixel circuit provided by the embodiments of FIG. 4, multiple groups of shift driving circuits may be arranged in the display panel. In an exemplary embodiment, the first shift driving circuit provides a scan signal PWM-S1; the second shift driving circuit provides a scan signal PWM-S2; the third shift driving circuit provides a first light-emitting control signal PWM-EM; the fourth shift driving circuit provides a scan signal PAM-S1; the fifth shift driving circuit provides a scan signal PAM-S2; and the sixth shift driving circuit provides a second light-emitting control signal PAM-EM. The swept-frequency signal SWEEP may be directly provided by a display driving chip, a shift driving circuit, or similar. When the swept-frequency signal SWEEP is provided by the shift driving circuit, a seventh shift driving circuit may also be arranged in the display panel. A clock signal CK, a clock signal XCK, a high level signal VGH, a low level signal VGL, and a start signal may enable any of the above-mentioned shift driving circuits. Embodiments utilizing a shift driving circuit may include a reset signal RST. For a type of shift driving circuit, various signals required for driving the shift driving circuit may be respectively provided with a corresponding signal bus 30. For the first shift driving circuit providing the scan signal PWM-S1, the display panel may be provided with a respective signal bus 30 for the clock signal CK, the clock signal XCK, the high level signal VGH and the low level signal VGL, respectively, and may further be provided with a signal bus 30 for providing a start signal.

Further, a short-circuiting bar may be further provided in the display panel, and a first data voltage PWM-data may be provided to the pixel circuit through the short-circuiting bar. Therefore, the signal bus 30 in the display panel further may include a power data bus and a switch control line provided for the short-circuiting bar. A group of power data busses and switch control line may be provided for red light-emitting devices, green light-emitting devices and blue light-emitting devices, respectively.

For the second data voltage PAM-data, red light-emitting devices may share a second data voltage PAM-data-R, green light-emitting devices may share a second data voltage PAM-data-G, and blue light-emitting devices may share a second data voltage PAM-data-B. The signal bus 30 may also include three second data buses providing a second data voltage PAM-data.

Further, in some embodiments of the present disclosure, based on the embodiments of FIG. 4, the first driving circuit 001 may further include a seventh transistor, which may have a gate connected to the scan signal PWM-S2, a first electrode connected to a ground signal Sweep-GND, and a second electrode connected to a second electrode plate of the first capacitor C1. In such embodiments, the signal bus 30 in the display panel further includes a signal bus corresponding to the ground signal Sweep-GND.

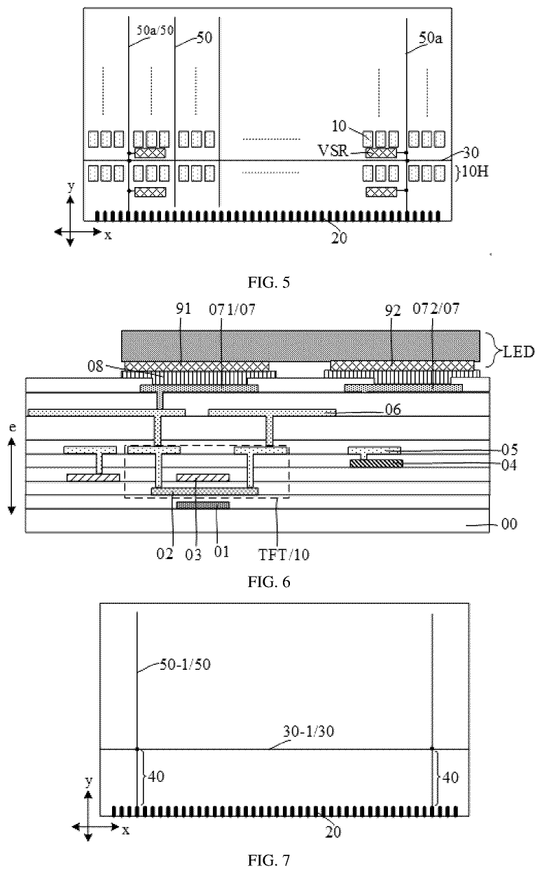

FIG. 5 is a simplified schematic diagram of another display panel according to an embodiment of the present disclosure. As shown in FIG. 5, the display panel may include a signal bus 30 extending along the first direction x and a first signal line 50 extending along the second direction y, the first signal line 50 includes sub-signal lines 50a, and the signal bus 30 is connected to two sub-signal lines 50a. A shift register unit VSR may be provided in the display region, and multiple shift register units VSR may be cascaded to form a shift driving circuit. For example, the shift register unit VSR may be arranged between adjacent pixel circuit rows 10H, and the shift register unit VSR may be electrically connected to the sub-signal line 50a. The sub-signal line 50a may be a signal line required for driving the shift register unit VSR, such as a clock signal line, or a high level signal line, a low level signal line, or the like. In an embodiment of the present disclosure, the shift driving circuit is arranged in the display region, which may reduce a frame of the display panel, thereby enabling the frameless display.

FIG. 6 is a structural schematic diagram of a film layer of a display panel according to an embodiment of the present disclosure. As shown in FIG. 6, the display panel may include a substrate 00, a light-shielding layer 01 arranged on the substrate 00, a semiconductor layer 02, a first metal layer 03, a second metal layer 04, a third metal layer 05, a fourth metal layer 06 and a fifth metal layer 07. FIG. 6 shows the position of one transistor TFT in the pixel circuit 10. In the illustrated embodiment, an active layer of the transistor TFT is located in the semiconductor layer 02. In a direction e perpendicular to a plane where the substrate 00 is located, the light-shielding layer 01 may overlap with the active layer of the transistor TFT. The light-shielding layer 01 may be configured to shield the active layer of the transistor TFT from light at the substrate 00 side, thereby preventing light from irradiating the active layer to affect the performance of the transistor TFT. A gate of the transistor TFT may be arranged in the first metal layer 03. For example, an electrode plate of the first capacitor C1 may be provided in the second metal layer 04, and another electrode plate of the first capacitor C1 may be provided in the first metal layer 03. A source electrode and a drain electrode of at least part of the transistor TFT may be provided on the third metal layer 05. The first metal layer 03 and the second metal layer 04 may be made of a same material, including molybdenum, and the third metal layer 05 may include titanium and/or aluminum, for example, a titanium/aluminum/titanium structure.

Alternatively, a power supply structure (e.g., a power supply structure that respectively provides a first power voltage PWM-vdd and a second power voltage PAM-vdd) may be arranged in the fourth metal layer 06. An anode electrode 071 and a cathode electrode 072 may be arranged in the fifth metal layer 07, and the anode electrode 071 and the cathode electrode 072 may be configured to be bonded and connected to the light-emitting device LED. The first electrode 91 of the light-emitting device LED may be connected to the anode electrode 071 through a eutectic layer 08, and the second electrode 92 of the light-emitting device LED may be connected to the cathode electrode 072 through the eutectic layer 08. The anode electrode 071 may be electrically connected to the pixel circuit. The fourth metal layer 06 and the fifth metal layer 07 may be made of the same material as the third metal layer 05, including titanium and/or aluminum.

In an embodiment of the present disclosure, the film layer where the first line segment 31 is located may be arranged at a side, away from the substrate 00, of the film layer where the second line segment 32 is located. Referring to FIG. 6, the first line segment 31 may be located in the third metal layer 05, and the second line segment 32 may be located in the first metal layer 03. A material of the first line segment 31 may include titanium and/or aluminum, and a material of the second line segment 32 may include molybdenum. Referring to FIG. 3, the second line segment 32 may span an arrangement region of the first signal line 50 between two adjacent pixel circuit groups 10Z. When the second line segment 32 is arranged in the first metal layer 03, the first signal line 50 may be arranged in the third metal layer 05. The second metal layer 04 and insulating layers between the metal layers may be further spaced between the first metal layer 03 and the third metal layer 05, such that a spacing between the first signal line 50 and the second line segment 32 is relatively large. This may reduce a coupling capacitance between the first signal line 50 and the second line segment 32, reducing the adverse effect on signal transmission.

In some other embodiments of the present disclosure, the signal bus 30 further includes a third line segment, such that the third line segment and the second line segment 32 are located in a same layer and electrically connected to one another alternately to form an entire signal line extending along the first direction x. The third line segment may ov with the first line segment 31 in the direction perpendicular to the plane where the substrate is located. In an embodiment of the present disclosure, an entire signal line formed by the third line segment and the second line segment 32 is connected in parallel with at least the first line segment 31 to form the signal bus 30, so as to reduce the resistance of the signal bus 30, reduce the risk of electrostatic accumulation of the signal bus 30, and improve the performance reliability of the display panel.

As shown in FIG. 3, at least two pixel circuits 10 may be arranged in the first direction x to form a pixel circuit group 10Z. One of the pixel circuit rows 10H may include a plurality of pixel circuit groups 10Z, and the pixel circuit groups 10Z may be arranged in the second direction y to form a pixel circuit group column 10L. In some embodiments, the display panel further includes a first signal line 50 extending along the second direction y, and the first signal line 50 is arranged between adjacent pixel circuit group columns 10L. Along the second direction y, the first line segment 31 may overlap with the pixel circuit group 10Z; and the first line segment 31 and the first signal line 50 may be arranged in the same layer. It can be seen from the top view of FIG. 3 that the second line segment 32 may at least partially overlap with the first signal line 50 in the direction perpendicular to the plane where the substrate is located. That is, the second line segment 32 may span the arrangement region of the first signal line 50 between two adjacent pixel circuit group columns 10L. The first line segment 31 and the first signal line 50 may be arranged in the same layer. For example, the first line segment 31 and the first signal line 50 may be arranged in the third metal layer 05, and the second line segment 32 may be arranged in the first metal layer 03, such that the metal layer in the display panel can be reasonably utilized, which not only reduces the overall resistance of the signal bus 30, reduces the risk of electrostatic accumulation on the signal bus 30, and improves the performance reliability of the display panel, but also reduces the coupling capacitance generated by overlapping the signal bus 30 and the first signal line 50.

FIG. 7 is a simplified schematic diagram of another display panel according to an embodiment of the present disclosure. It should be understood that, in order to clearly illustrate a connection manner between the signal bus 30 and the signal terminal 20, FIG. 7 does not show the pixel circuit and other structures. As shown in FIG. 7, the signal bus 30 may include a first signal sub-bus 30-1, the first signal line 50 may include a first sub-signal line 50-1, and the first sub-signal line 50-1 may include a connection line segment 40. In some embodiments, the connection line segment 40 belongs to a part of the first sub-signal line 50-1—that is, an end of the first sub-signal line 50-1 is connected to the signal terminal 20. In an example embodiment, the second line segment 32 in the first signal sub-bus 30-1 is connected to the first sub-signal line 30-1 through a via. For reference, FIG. 7 does not show the first line segment 31 and the second line segment 32 that are arranged in the first signal sub-bus 30-1, and the position of the second line segment 32 can be understood with reference to FIG. 3. In an embodiment of the present disclosure, a part of line segments in the first sub-signal line 50-1 are reused as the connection line segments 40, so that the first sub-signal line 50-1 is directly connected to the corresponding signal terminal 20, without the requirement of any additional connection line segment 40, which is beneficial to saving the wiring space of the display panel. In the embodiments of the present disclosure, the number of the first sub-signal lines 50-1 correspondingly connected to the first signal sub-bus 30-1 is not limited. FIG. 7 only shows that two first sub-signal lines 50-1 are correspondingly connected the first signal sub-bus 30-1 as an example.

In some embodiments, the first signal sub-bus 30-1 is a type of signal bus 30 in the display panel, and a plurality of first signal sub-buses 30-1 respectively transmitting different signals are provided in the display panel. For example, the first signal sub-bus 30-1 may include a clock signal bus, a high-level signal bus, a low-level signal bus, and the like required for driving the shift driving circuit.

FIG. 8 is a simplified schematic diagram of another display panel according to an embodiment of the present disclosure. As shown in FIG. 8, the signal bus 30 may include a second signal sub-bus 30-2, and the second signal sub-bus 30-2 may be connected to a corresponding signal terminal 20 through a connection line segment 40. The first signal line 50 may include a second sub-signal line 50-2, which may be connected to the second signal sub-bus 30-2 through a transistor T. In some embodiments, the signal bus 30 further includes a third signal sub-bus 30-3 connected to a control end (gate) of the transistor T, and the third signal sub-bus 30-3 is connected to a corresponding signal terminal 20 through a connection line segment 40. FIG. 8 shows one second signal sub-bus 30-2 and one third signal sub-bus 30-3. In some embodiments, the second sub-signal line 50-2 is a data line for transmitting the first data voltage PWM-data. The second sub-signal lines 50-2 may be connected to the pixel circuits arranged in the second direction y. A plurality of second sub-signal lines 50-2 may be provided in the display panel. In some embodiments, the transistor T is a short-circuit bar required during a dot-screen testing. The third signal sub-bus 30-3 connected to a control end of the transistor T may be a switch control line, and the second signal sub-bus 30-2 connected to the first electrode of the transistor T may be a data bus (or referred to as a power line). The second sub-signal line 50-2 may be connected to the second electrode of the transistor T. During the dot-screen testing, the first data voltage PWM-data on the data bus may be provided to the second sub-signal line 50-2 using the short-circuiting bar, and the second sub-signal line 50-2 may further provide the data voltage to the pixel circuits connected thereto.

Further, as illustrated in FIG. 8 that the second sub-signal line 50-2 may be further connected to the corresponding signal terminal 20. During display, supplies may power to the second sub-signal line 50-2 to provide the first data voltage PWM-data required for display. At the same time, the signal terminal 20 may provide a signal to the third signal sub-bus 30-3 connected to the control end of the transistor T through the signal terminal 20, to control the transistor T to be in an off state. The signal terminal 20 may provide a constant voltage signal to the second signal sub-bus 30-2 connected to the first electrode of the transistor T through the signal terminal 20, to prevent a floating line of the panel from affecting the display effect during display.

In some embodiments of the present disclosure, as shown in FIG. 3, along the first direction x, a length of the first line segment 31 is d1, and a length of the pixel circuit group 10Z is d2, where d1≤d2. The length of the pixel circuit group 10Z may be calculated by the length occupied by three pixel circuits 10 in the first direction x. In an embodiment of the present disclosure, the first line segment 31 and the second line segment 32 are connected by a via, and the connected via between the first line segment 31 and the second line segment 32 overlaps with the pixel circuit group 10Z in the second direction y. Since a first signal line 50 is provided on both sides of the pixel circuit group 10Z along the first direction x, the first line segment 31 and the first signal line 50 may be manufactured in the same metal layer, and the length of the first line segment 31 is limited, which may ensure the process yield when the first line segment 31 and the first signal line 50 are manufactured in the same layer.

It should be noted that, when calculating the length occupied by the pixel circuit 10 in the first direction x, the edges of the transistors at an edge position on both sides of the pixel circuit 10 in the first direction x may be used as boundaries.

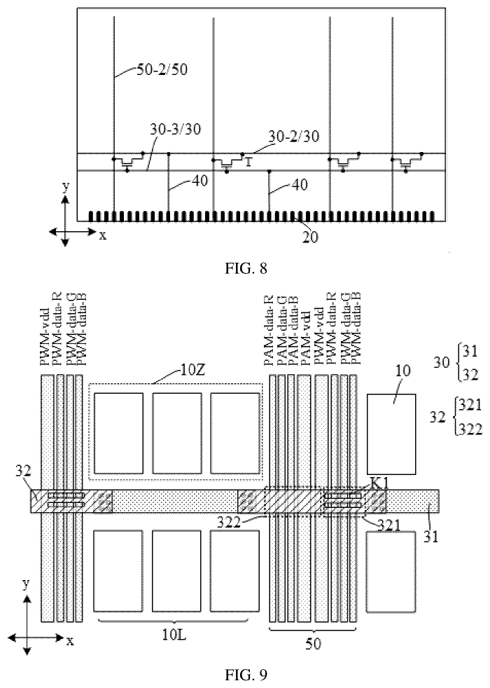

FIG. 9 is a partial schematic diagram of another display panel according to an embodiment of the present disclosure. As shown in FIG. 9, n first signal lines 50 may be provided between two adjacent pixel circuit group columns 10L, where n is an integer, and n>2. It should be understood that FIG. 9 only simplifies the number and line width of the first signal lines 50. The second line segment 32 may include a first sub-segment 321 and a second sub-segment 322 connected to each other. FIG. 9 is a top view of a display panel, and it can be seen from the top view of this exemplary embodiment that along the direction perpendicular to the plane where the substrate is located, a first sub-segment 321 overlaps with at least one first signal line 50, and a second sub-segment 322 overlaps with at least one first signal line 50. The first sub-segment 321 has a first slot K1 extending along the first direction x. In an embodiment of the present disclosure, a part of sub-segments of the second line segment 32 has a first slot K1, that is, a length of the first slot K1 in the first direction x is less than a width occupied by the n first signal lines 50 in the first direction x. The first slot K1 is provided on the second line segment 32, which may reduce the parasitic capacitance generated between the second line segment 32 and the first signal line 50 overlapping therewith, and reduce the power consumption. While the first slot K1 is only provided on a part of sub-segments of the second line segment 32, which may reduce the influence of the slot on the resistance of the second line segment 32.

Taking the display panel including the pixel circuit shown in FIG. 4 as an example, the n first signal lines 50 arranged between two adjacent pixel circuit groups 10L at least include a first data line PWM-data-R, a first data line PWM-data-G, and a first data line PWM-data-B that respectively provide a first data voltage PWM-data to the red light-emitting devices, the green light-emitting devices and the blue light-emitting devices, a first power voltage line PWM-vdd that provides a first power voltage PWM-vdd, a second data line PAM-data-R, a second data line PAM-data-G, and a second data line PAM-data-B that respectively provide a second data voltage PAM-data to the red light-emitting devices, the green light-emitting devices and the blue light-emitting devices, and a second power voltage line PAM-vdd that provides a second power voltage PAM-vdd.

It should be noted that, in order to clearly illustrate the first slot K1 on the second line segment 32, in FIG. 9, the film layer where the first signal line 50 is located is drawn below the film layer where the second line segment 32 is located. In an embodiment of the present disclosure, the film layer where the first line segment 31 is located is arranged on a side of the film layer where the second line segment 32 is located away from the substrate, and the first signal line 50 and the first line segment 31 are located in a same layer. FIG. 9 is a partial top view of the display panel viewed from the side of the substrate.

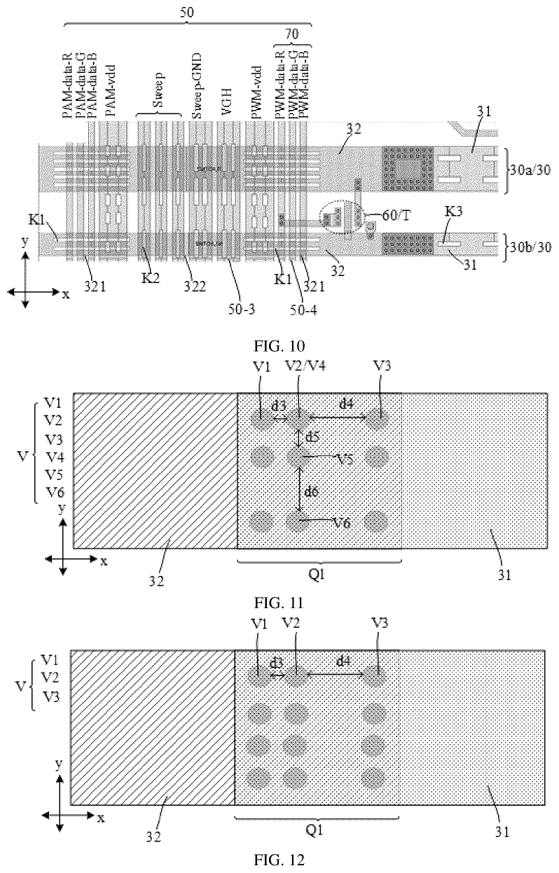

FIG. 10 is a partial schematic diagram of another display panel according to an embodiment of the present disclosure. According to the exemplary embodiment shown in FIG. 10, at least one of the first signal lines 50 overlapping with the second sub-segment 322 has a second slot K2 extending along the second direction y. It can be seen from the partial top view shown in FIG. 10 that the second sub-segment 322 at least partially overlaps with the second slot K2 along the direction perpendicular to the plane where the substrate is located. In an embodiment of the present disclosure, the first signal line 50 overlapping with the second sub-segment 322 has the second slot K2, which may further reduce the parasitic capacitance between the second line segment 32 and the first signal line 50 and reduce the power consumption.

According to the exemplary embodiment shown in FIG. 10, the first signal line 50 overlapping with the second sub-segment 322 includes at least one third sub-signal line 50-3, and the first signal line 50 overlapping with the first sub-segment 321 includes at least one fourth sub-signal line 50-4. The third sub-signal line 50-3 has a second slot K2. In the first direction x, a width of the third sub-signal line 50-3 is greater than a width of the fourth sub-signal line 50-4. In an embodiment of the present disclosure, in the region where the second line segment 32 overlaps with the n first signal lines 50, the first signal line 50 has the first slot K1 at a partial region position, and the first signal line 50 has the second slot K2 at a partial region position. The slots may reduce the parasitic capacitance between the second line segment 32 and the first signal line 50, the load, and thus the power consumption. When the slot is formed, a line width of the first signal line 50 is also considered. The first slot K1 is formed on the second line segment 32 (i.e., on the first sub-segment 321) at the position where the second line segment 32 overlaps with at least part of the first signal line 50 having a smaller line width, and the second slot K2 is formed on the first signal line 50 (i.e., on the third sub-signal line 50-3) at the position where the second line segment 32 overlaps with at least part of the first signal line 50 having a larger line width, which not only makes full use of the first signal line 50 having the larger line width, but also ensures that the length of the first slot K1 on the second line segment 32 is not too long to affect the resistance of the second line segment 32.

In some embodiments of the present disclosure, as shown in FIG. 10, the first signal line 50 includes a first data line PWM-data-R, a first data line PWM-data-G, and a first data line PWM-data-B that respectively provide a first data voltage PWM-data to the red light-emitting devices, the green light-emitting devices and the blue light-emitting devices, a first power voltage line PWM-vdd that provides a first power voltage PWM-vdd, a second data line PAM-data-R, a second data line PAM-data-G, and a second data line PAM-data-B that respectively provide a second data voltage PAM-data to the red light-emitting devices, the green light-emitting devices and the blue light-emitting devices, and a second power voltage line PAM-vdd that provides a second power voltage PAM-vdd. The first signal line 50 may further include a high level signal line VGH, a ground signal line SWEEP-GND that provides a ground signal, and a swept-frequency signal Sweep.

Further, it can be seen from FIG. 10 that the first power voltage line PWM-vdd overlapping with the first sub-segment 321 may also have a slot. That is, the embodiment of the present disclosures do not exclude the situation that, the first slot K1 is formed on the first sub-segment 321, and meanwhile the slot is formed on the first signal line 50 overlapping with the first sub-segment 321. The first power voltage line PWM-vdd may have a relatively large line width, and the slot formed on the first power voltage line PWM-vdd may prevent the problem of process instability caused by a large area of metal. The area of the continuous first power voltage line PWM-vdd may be reduced through the slot, and thus the process stability is improved.

In some embodiments of the present disclosure, as shown in FIG. 10, a third slot K3 is formed on the first line segment 31, and the area of the first line segment 31 may be reduced, the problem of process instability caused by a large area of metal can be prevented, and the process stability may be improved through the third slot K3.

In some embodiments of the present disclosure, the second line segment 32 includes two first sub-segments 321 and one second sub-segment 322 that is connected to and between the two first sub-segments 321. In an embodiment of the present disclosure, the first slot K1 formed on the second line segment 32 does not spans the arrangement region of the n first signal lines 50, such that the first slot K1 has relatively a slight effect on the overall pattern of the second line segment 32, thereby avoiding a sharp increase in the resistance of the signal bus 30 caused by the arrangement of the first slot K1.

As shown in FIG. 10, the signal bus 30 may include a data bus 30a and a switch control line 30b. The display panel may include a short-circuiting bar 60 and a first data line 70 extending along the second direction y, and the short-circuiting bar 60 includes a transistor T. The short-circuiting bar 60 may include a control end connected to the switch control line 30b, a first end connected to the data bus 30a, and a second end connected to the first data line 70. The first data line 70 may include a first data line PWM-data-R, a first data line PWM-data-G, and a first data line PWM-data-B that respectively provide a first data voltage PWM-data to the red light-emitting devices, the green light-emitting devices, and the blue light-emitting devices. FIG. 10 shows a short-circuiting bar 60 connected to a first data line PWM-data-R.

FIG. 11 is an enlarged schematic diagram of a position Z shown in FIG. 3, and FIG. 11 only shows a position where the first line segment 31 is connected to the second line segment 32 through a via. According to the exemplary embodiment shown in FIG. 11, the first line segment 31 is connected to the second line segment in a first region Q1, and the first region Q1 includes a plurality of vias V. The vias V include a first via V1, a second via V2 and a third via V3. In the first direction x, the first via V1 is adjacent to the second via V2, and the second via V2 is adjacent to the third via V3. A spacing between the first via V1 and the second via V2 is d3, and a spacing between the second via V2 and the third via V3 is d4, d3≠d4. The vias V in the first region Q1 include a fourth via V4, a fifth via V5 and a sixth via V6. In the second direction y, the fourth via V4 is adjacent to the fifth via V5, and the fifth via V5 is adjacent to the sixth via V6. A spacing between the fourth via V4 and the fifth via V5 is d5, and a spacing between the fifth via V5 and the sixth via V6 is d6, d5≠d6.

According to the exemplary embodiment shown in FIG. 11, in the first region Q1, the vias V are arranged in the first direction x, and the vias V are arranged in the second direction y. The first line segment 31 is connected to the second line segment using the vias V, which can reduce the connection impedance. Moreover, the vias V are not spaced equally along the first direction x, and the vias V are also not spaced equally along the second direction y. The first region Q1 includes densely arranged areas and sparsely arranged areas of the vias, which can prevent the vias V from being densely arranged, and prevent serious via corrosion, thereby improving the performance reliability of the display panel.

Further, in an embodiment of the present disclosure, a shape of the via V is not limited. FIG. 11 only shows that the shape of the via V is a circle.

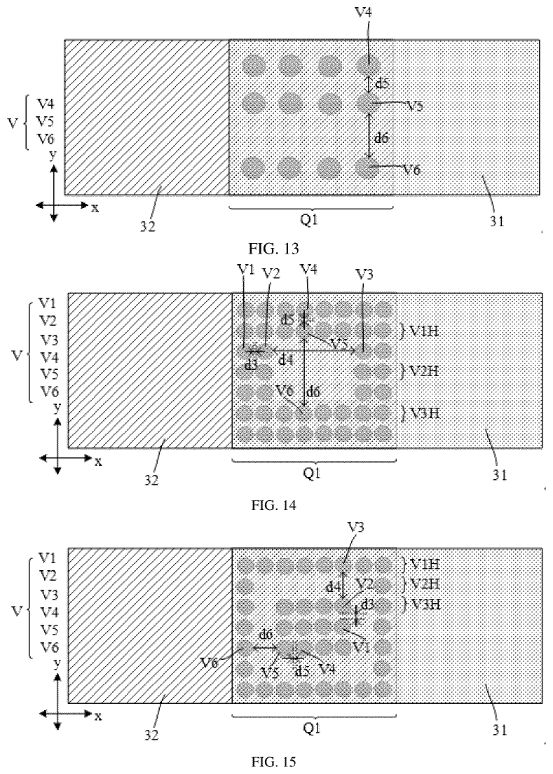

FIG. 12 is another enlarged schematic diagram of a region Z shown in FIG. 3 According to the exemplary embodiment shown in FIG. 12, the via V in the first region Q1 includes a fourth via V4, a fifth via V5 and a sixth via V6. In the first direction x, the first via V1 is adjacent to the second via V2, and the second via V2 is adjacent to the third via V3. A spacing between the first via V1 and the second via V2 is d3, and a spacing between the second via V2 and the third via V3 is d4, d3≠d4. In the embodiments of FIG. 12, the vias V are not spaced equally in the first direction x, but the vias V are substantially spaced equally in the second direction y.

FIG. 13 is another enlarged schematic diagram of a region Z shown in FIG. 3. According to the exemplary embodiment shown in FIG. 13, in the first region Q1, the via V includes a first via V1, a second via V2 and a third via V3. In the second direction y, the fourth via V4 is adjacent to the fifth via V5, and the fifth via V5 is adjacent to the sixth via V6. A spacing between the fourth via V4 and the fifth via V5 is d5, and a spacing between the fifth via V5 and the sixth via V6 is d6, d5≠d6. In the embodiments of FIG. 13, the vias V are substantially spaced equally in the first direction x, but the vias V are not spaced equally in the second direction y.

FIG. 14 is another enlarged schematic diagram of a region Z shown in FIG. 3. According to the exemplary embodiment shown in FIG. 14, in the first region Q1, the vias V include a first circle of vias and a second circle of vias. FIG. 14 does not indicate the first circle of vias and the second circle of vias, in which the first circle of vias surrounds the second circle of vias, and a spacing between the first circle of vias and the second circle of vias is relatively small. The first circle of vias and the second circle of vias are arranged to form square ring-shaped vias. In these above embodiments of the present disclosure, the number of the vias V arranged in the first region Q1 is relatively large, which can facilitate reducing the connection impedance between the first line segment 31 and the second line segment 32.

In some embodiments of the present disclosure, as shown in FIG. 14, the first via V1 may be located in the first circle of vias, and the second via V2 and the third via V3 are located in the second circle of vias. A spacing between the first via V1 and the second via V2 is d3, and a spacing between the second via V2 and the third via V3 is d4, d3<d4. The fourth via V4 may be located in the first circle of vias, and the fifth via V5 and the sixth via V6 may be located in the second circle of vias. A spacing between the fourth via V4 and the fifth via V5 is d5, and a spacing between the fifth via V5 and the sixth via V6 is d6, d5<d6. In an embodiment of the present disclosure, the first circle of vias are arranged in a peripheral region of the first region Q1, and the second circle of vias are arranged inside the first circle of vias and close to the first circle of vias, so that the number of vias V arranged in the second circle of vias can be as large as possible, and the number of the arranged vias may be greater while ensuring that the vias in the first region Q1 are not densely arranged, which is beneficial to reducing the connection impedance between the first line segment 31 and the second line segment 32.

The embodiments of FIG. 14 may be described from another perspective. FIG. 14 shows that the vias V in the first region Q1 are arranged into via rows in the first direction x. The via rows may include a first via row V1H, a second via row V2H and a third via row V3H. Along the second direction y, the second via row V2H may be located between the first via row V1H and the third via row V3H. A number of the vias V in the second via row V2H may be less than a number of the vias V in the first via row V1H, and the number of the vias V in the second via row V2H may be less than a number of the vias V in the third via row V3H. As shown in FIG. 14, the vias may be first arranged in a regular array in the first region Q1, and then some of the vias at the center of the via array may be removed to obtain at least one second via row V2H, thereby avoiding dense arrangement of a large number of vias V, preventing serious via corrosion, and improving the performance reliability of the display panel.

FIG. 15 is another enlarged schematic diagram of a region Z shown in FIG. 3. According to the exemplary embodiment shown in FIG. 15, in the first region Q1, the vias V include a first circle of vias and a second circle of vias. FIG. 15 does not mark the first circle of vias and the second circle of vias, in which the first circle of vias surrounds the second circle of vias, and a spacing between the first circle of vias and the second circle of vias is relatively large. The first vias are arranged in a peripheral region of the first region Q1, and the second vias are arranged in a central region of the first region Q1. FIG. 15 shows that the first circle of vias include a third via V3 and a sixth via V6, and the second circle of vias include a first via V1, a fourth via V4, a second via V2 and a fifth via V5.

The embodiments of FIG. 15 may be described from another perspective. As shown in FIG. 15, the vias V in the first region Q1 may be arranged into via rows in the first direction x. The via rows may include a first via row V1H, a second via row V2H and a third via row V3H. Along the second direction y, the second via row V2H may be located between the first via row V1H and the third via row V3H. A number of the vias V in the second via row V2H may be less than a number of the vias V in the first via row V1H, the number of the vias V in the second via row V2H may be less than a number of the vias V in the third via row V3H, and the number of the vias V in the third via row V3H may be less than the number of the vias V in the first via row V1H. As shown in FIG. 15, the vias may be first arranged in a regular array in the first region Q1, and then some vias in some via rows may be removed to form the second via row V2H and the third via row V3H, thereby avoiding dense arrangement of a large number of vias V, preventing serious via corrosion, and improving the performance reliability of the display panel.

According to the exemplary embodiment shown in FIG. 15, the pattern of the vias in the first region Q1 may also be considered to be obtained by first arranging the vias in a regular array in the firs region Q1, retaining the vias at the center position of the via array and the outermost circle of vias, and removing at least one circle of vias in the inner circle of the via array.

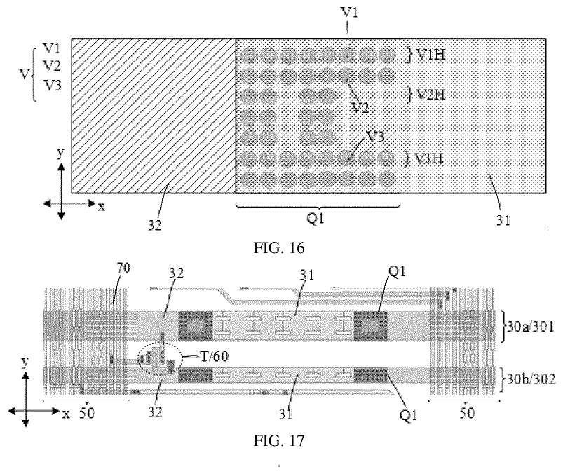

FIG. 16 is another enlarged schematic diagram of a region Z shown in FIG. 3. According to the exemplary embodiment shown in FIG. 16, in the first region Q1, the vias V are arranged into via rows in the first direction x. The via rows include a first via row V1H, a second via row V2H and a third via row V3H. Along the second direction y, the second via row V2H is located between the first via row V1H and the third via row V3H. A number of the vias V in the second via row V2H is less than a number of the vias V in the first via row V1H, and the number of the vias V in the second via row V2H is less than a number of the vias V in the third via row V3H. In an embodiment of the present disclosure, the vias are first arranged in a regular array, and then some vias in some via rows are removed to form the second via row V2H, thereby avoiding dense arrangement of a large number of vias V, preventing serious via corrosion, and improving the performance reliability of the display panel.

FIG. 17 is a partial schematic diagram of another display panel according to an embodiment of the present disclosure. According to the exemplary embodiment shown in FIG. 17, the signal bus 30 includes a first signal bus 301 and a second signal bus 302, and a line width of the first signal bus 301 is greater than a line width of the second signal bus 302. The first region Q1 of the first signal bus 301 includes a first via V1, a second via V2, and a third via V3, and/or includes a fourth via V4, a fifth via V5, and a sixth via V6. FIG. 17 does not indicate the first via to the sixth via V1. . . . V6, and the features of the first via to the sixth via V1. . . . V6 can be understood with reference to FIG. 11 to FIG. 16. In the first direction x, the first via V1 is adjacent to the second via V2, and the second via V2 is adjacent to the third via V3. A spacing between the first via V1 and the second via V2 is d3, and a spacing between the second via V2 and the third via V3 is d4, d3≠d4. And/or, in the second direction y, the fourth via V4 is adjacent to the fifth via V5, and the fifth via V5 is adjacent to the sixth via V6. A spacing between the fourth via V4 and the fifth via V5 is d5, and a spacing between the fifth via V5 and the sixth via V6 is d6, d5≠d6. In the first region Q1 of the second signal bus 302, the vias are arranged in a via array having a rows and b columns, in which a and b are integers, a≥2, and b≥2. FIG. 17 illustrates a=3, and b=8 as an example.

According to the exemplary embodiment shown in FIG. 17, in the signal buses 30, the arrangement of the vias in the first region Q1, where the first line segment 31 and the second line segment 32 are connected to each other, is differentiated based on the difference of the line widths thereof. For the first signal bus 301 having a larges line width, the vias arranged in the first direction x are not spaced equally and/or the vias arranged in the second direction y are not spaced equally in the first region Q1 of the first signal bus 301, which can prevent the vias from being densely arranged, and prevent serious via corrosion, thereby improving the performance reliability of the display panel. For the second signal bus 302 with a smaller line width, the vias arranged in the first region Q1 in a regular array can reduce the connection impedance between the first line segment 31 and the second line segment 32.

According to the exemplary embodiment shown in FIG. 17, the first signal bus 301 includes a data bus 30a, and the second signal bus 302 includes a switch control line 30b. That is, a line width of the data bus 30a is larger than a line width of the switch control line 30b, thereby reducing the voltage drop of the data bus 30a, and ensuring the power supply capability of the data bus 30a. The display panel includes a short-circuiting bar 60 located between adjacent rows of pixel circuits 10 and a first data line 70 extending along the second direction y. The short-circuiting bar 60 has a control end connected to the switch control line 30b, a first end connected to the data bus 30a, and a second end connected to the first data line 70. In an example, the short-circuiting bar 60 includes a transistor T, and the transistor T has a gate connected to the switch control line 30b, a first electrode connected to the data bus 30a, and a second electrode connected to the first data line 70.

Further, in different embodiments of the present disclosure, the signal bus is classified and named from different perspectives, and the classification and naming of the signal bus are described herein. According to the exemplary embodiment shown in FIG. 17, the signal buses 30 are classified into a first signal bus 301 and a second signal bus 302 according to different line widths of the signal buses 30. In the above embodiments of FIG. 7 and FIG. 8, the signal bus 30 is classified into a first signal sub-bus 30-1 and a second signal sub-bus 30-2 according to a connection manner between the signal bus 30 and the first signal line 50. In some embodiments of the present disclosure, for example, when the data bus 30 is classified according to the line width of the signal bus 30, the data bus 30 is the first signal bus 301 having a wider line width, and when the data bus 30 is classified according to the connection manner between the signal bus 30 and the first signal line 50, the data bus 30 is the second signal sub-bus 30-2.

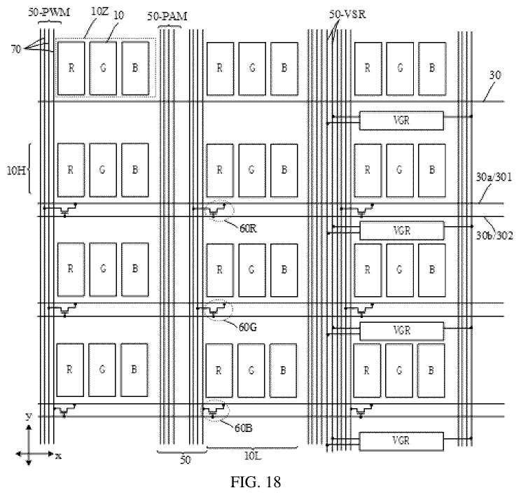

FIG. 18 is a partial schematic diagram of another display panel according to an embodiment of the present disclosure. According to the exemplary embodiment shown in FIG. 18, the pixel circuit 10 includes a first pixel circuit R for driving a red light-emitting device, a second pixel circuit G for driving a green light-emitting device, and a third pixel circuit B for driving a blue light-emitting device. The first signal lines 50 between adjacent pixel circuit group columns 10L include at least a first signal line 50-PWM for driving a first driving circuit in the pixel circuit, and a first driving signal line 50-PAM for driving a second driving circuit in the pixel circuit. It can be seen from the relevant description in FIG. 9 that, the first signal line 50-PWM includes a first data line PWM-data-R, a first data line PWM-data-G, a first data line PWM-data-B that provide a first data voltage PWM-data, and a first power voltage line PWM-vdd that provides a first power voltage PWM-vdd. The first driving signal line 50-PAM includes a second data line PAM-data-R, a second data line PAM-data-G, a second data line PAM-data-B that provide a second data voltage PAM-data, and a second power voltage line PAM-vdd that provides a second power voltage PAM-vdd.

The first data line 70 connected to the short-circuiting bar 60 may be configured to provide the first data voltage PWM-data required by the first driving circuit 001 in the embodiments of FIG. 4. The first data line 70 may include a first data line PWM-data-R, a first data line PWM-data-G, and a first data line PWM-data-B. The short-circuiting bars 60 may include a short-circuiting bar 60-R connected to the first data line PWM-data-R, a short-circuiting bar 60-G connected to a first data line PWM-data-G, and a short-circuiting bar 60-B connected to a first data line PWM-data-B. A data bus 30a and a switch control line 30b respectively may be provided for each group of short-circuit bars. That is, three data buses 30a and three switch control lines 30b may be arranged in the display panel.

In some embodiments of the present disclosure, the three data buses 30a have the same line width, and the three switch control lines 30b have the same line width. A line width of the data bus 30a may be greater than a line width of the switch control line 30b. In addition, other signal buses 30 in the display panel may be designed with the same line width.

In some embodiments of the present disclosure, as shown in FIG. 18, the shift register units VSR are located between adjacent pixel circuit rows 10H, and a plurality of cascaded shift register units VSR form a shift driving circuit. In this case, the first signal line 50 further includes driving lines 50-VSR for driving the shift driving circuit. FIG. 18 only schematically shows the number of the driving lines 50-VSR. The driving lines 50-VSR of the shift driving circuit at least include a start signal line, a pair of clock signal lines, a high level signal line and a low level signal line. In an embodiment of the present disclosure, the shift register unit VSR is arranged between adjacent pixel circuit rows 10H, that is, the shift driving circuit is arranged in the display region of the display panel, thereby reducing the frame of the display panel to achieve the frameless display.

In some embodiments of the present disclosure, as shown in FIG. 18, the signal bus 30 includes a data bus 30a and a switch control line 30b. The display panel may include a short-circuiting bar 60 located between adjacent pixel circuit rows 10H and a first data line 70 extending along the second direction y. The short-circuiting bar 60 may have a control end connected to the switch control line 30b, a first end connected to the data bus 30a, and a second end connected to the first data line 70. The data bus 30a and the switch control line 30b that are connected to the same short-circuiting bar 60 may be located between two adjacent pixel circuit rows 10H. Such arrangement can facilitate the connection between the short-circuiting bar 60 and the data bus 30a and the switch control line 30b, thereby shortening the connection wires, and saving the layout space of the display panel.

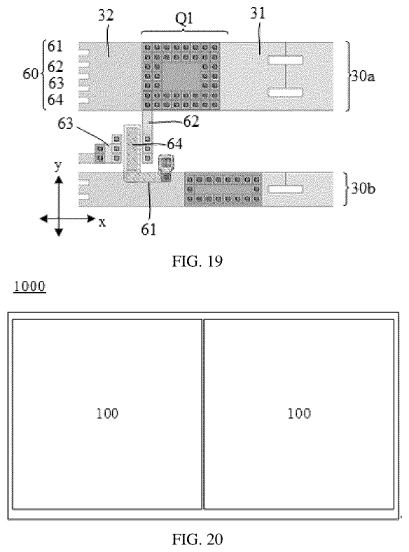

FIG. 19 is a partial schematic diagram of another display panel according to an embodiment of the present disclosure. FIG. 19 only shows partial positions of the data bus 30a and the switch control line 30b. According to the exemplary embodiment shown in FIG. 19, the short-circuiting bar 60 includes a gate electrode 61, a source electrode 62, a drain electrode 63 and an active layer 64. The source electrode 62 and the first line segment 31 are arranged in the same layer and formed as an integrated structure, so that the source electrode 62 is connected to the data bus 30a. In addition, the gate electrode 61 is connected to the switch control line 30b, and the drain electrode 63 is connected to the corresponding first data line. With reference to the structural diagram of the film layer structure shown in FIG. 6, the gate electrode 61 is located in the first metal layer 03, the source electrode 62 and the drain electrode 63 are located in the third metal layer 05, and the active layer 64 is located in the semiconductor layer 02. The first line segment 31 is located in the third metal layer 05, and the second line segment 32 is located in the first metal layer 03. In an embodiment of the present disclosure, the source electrode 62 and the first line segment 31 are arranged in the same layer and are formed as an integrated structure, so that the source electrode 62 is electrically connected to the data bus 30a, without connecting the source electrode 62 and the second line segment 32 through a via, which can reduce the number of vias. In conjunction with FIG. 17, in the embodiments of FIG. 19, no via needs to be provided between the first region Q1 of the data bus 30a and the first signal line 50 adjacent thereto, which is beneficial to shortening a distance between the first region Q1 and the first signal line 50 adjacent thereto, and the length of the corresponding first line segment 31 may also be configured longer, thereby facilitating reducing the risk of electrostatic accumulation of the data bus 30a.

In the embodiments of FIG. 19, the source electrode 62 and the first line segment 31 are located in the same layer and are arranged in an integral structure. A shape of the source electrode 62 may be a long strip extending along the second direction y. The first region Q1 at least partially overlaps with the short-circuiting bar 60 in the second direction y.

In some other embodiments of the present disclosure, the source electrode 62 and the first line segment 31 are located in the same layer and are arranged in an integral structure. A shape of the source electrode 62 may be L-shaped or in other shapes. The first region Q1 does not overlap with the short-circuiting bar 60 in the second direction y, which is not illustrated herein.

Based on the same inventive concept, an embodiment of the present disclosure further provides a display device, the display device including the display panel provided by any embodiment of the present disclosure. A structure of the display panel has been described in the above-mentioned embodiments, and will not be repeated herein. The display device provided by the embodiments of the present disclosure may be, for example, an electronic device having a display function, such as a mobile phone, a tablet, a computer, a television, and a smart wearable product. The display device provided by the embodiments of the present disclosure may also be a transparent display device, such as a transparent display window; or may also be a spliced display device, such as a large conference room screen, and a large exhibition hall screen.

FIG. 20 is a schematic diagram of a display device according to an embodiment of the present disclosure. According to the exemplary embodiment shown in FIG. 20, the display device 1000 includes the display panel 100 according to any embodiment of the present disclosure. The structure of the display panel 100 has been described in the above-mentioned embodiments, which will not be repeated herein. The display device 1000 according to an embodiment of the present disclosure is formed by splicing at least two display panels 100. FIG. 20 indicates that the display device 1000 includes two display panels 100 as an example.

The above description merely illustrates some preferred embodiments of the present disclosure, but is not intended to limit the present disclosure, and any modification, equivalent substitution, improvement and the like made within a spirit and a principle of the present disclosure shall fall with a scope of the present disclosure.

As above, it should be noted that, the above-described embodiments are merely for illustrating the present disclosure but not intended to provide any limitation. Although the present disclosure has been described in detail with reference to the above-described embodiments, it should be understood that those skilled in the art may also modify the technical solutions described in the above embodiments or equivalently replace some or all of the technical features therein, but these modifications or replacements do not cause the essence of corresponding technical solutions to depart from the scope of the present disclosure.

What is claimed is:

1. A display panel, comprising:
a substrate;
a plurality of pixel circuits, wherein the plurality of pixel circuits are provided in a first direction to form a plurality of pixel circuit rows, and the plurality of pixel circuit rows are arranged in a second direction;
a plurality of signal terminals provided at a side of the plurality of pixel circuit rows in the second direction;
a signal bus extending in the first direction and arranged between two adjacent pixel circuit rows; and
a connection line segment extending in the second direction,
wherein the plurality of pixel circuits, the plurality of signal terminals, the signal bus, and the connection line segment are arranged at a side of the substrate, and the first direction intersects with the second direction;
wherein a first end of the connection line segment is electrically connected to the signal bus, and a second end of the connection line segment is electrically connected to at least one of the plurality of signal terminals; and
wherein the signal bus comprises a first line segment and a second line segment, and the first line segment and the second line segment are arranged in the first direction and in different layers.

2. The display panel according to claim 1, wherein
at least two of the plurality of pixel circuits are arranged in the first direction to form a pixel circuit group, one of the pixel circuit rows comprises a plurality of pixel circuit groups arranged in the second direction to form a pixel circuit group column;
the display panel further comprises a first signal line extending along the second direction, and the first signal line is arranged between adjacent pixel circuit group columns; and
along the second direction, the first line segment overlaps with the pixel circuit group; the first line segment and the first signal line are arranged in a same layer; and along a direction perpendicular to a plane of the substrate, the second line segment at least partially overlaps with the first signal line.

3. The display panel according to claim 2, wherein
the signal bus comprises a first signal sub-bus; and
the first signal line comprises a first sub-signal line comprising the connection line segment; and the second line segment in the first signal sub-bus is connected to the first sub-signal line through a via.

4. The display panel according to claim 2, wherein
the signal bus comprises a second signal sub-bus; and
the first signal line comprises a second sub-signal line connected to the second signal sub-bus through a transistor.

5. The display panel according to claim 2, wherein
in the first direction, a length of the first line segment is d1, and a length of the pixel circuit group is d2, wherein d1≤d2.

6. The display panel according to claim 2, wherein
n first signal lines are provided between two adjacent pixel circuit group columns, wherein n is an integer, and n≥2;
the second line segment comprises a first sub-segment and a second sub-segment that are connected to each other, and along the direction perpendicular to the plane of the substrate, the first sub-segment overlaps with at least one of the first signal lines, and the second sub-segment overlaps with at least one of the first signal lines; and
the first sub-segment has a first slot extending along the first direction.

7. The display panel according to claim 6, wherein
at least one of the first signal lines overlapping with the second sub-segment has a second slot extending along the second direction, and along the direction perpendicular to the plane of the substrate, the second sub-segment at least partially overlaps with the second slot.

8. The display panel according to claim 7, wherein
the first signal lines overlapping with the second sub-segment comprise at least one third sub-signal line, the first signal lines overlapping with the first sub-segment comprise at least one fourth sub-signal line, and the third sub-signal line has the second slot; and
in the first direction, a width of the at least one third sub-signal line is greater than a width of the at least one fourth sub-signal line.

9. The display panel according to claim 6, wherein
the second line segment comprises two first sub-segments and one second sub-segment, and the second sub-segment is connected to and between the two first sub-segments.

10. The display panel according to claim 1, wherein
the first line segment is connected to the second line segment in a first region, and the first region comprises vias;
the vias comprise a first via, a second via and a third via, in the first direction, the first via is adjacent to the second via, the second via is adjacent to the third via, a spacing between the first via and the second via is d3, a spacing between the second via and the third via is d4, where d3≠d4; and/or
the vias comprise a fourth via, a fifth via and a sixth via, in the second direction, the fourth via is adjacent to the fifth via, the fifth via is adjacent to the sixth via, a spacing between the fourth via and the fifth via is d5, and a spacing between the fifth via and the sixth via is d6, where d5≠d6.

11. The display panel according to claim 10, wherein
in the first region, the vias comprise a first circle of vias and a second circle of vias, and the first circle of vias surround the second circle of vias.

12. The display panel according to claim 11, wherein
the first via is located in the first circle of vias, the second via and the third via are located in the second circle of vias, and d3<d4; and/or
the fourth via is located in the first circle of vias, the fifth via and the sixth via are located in the second circle of vias, and d5<d6.

13. The display panel according to claim 10, wherein
in the first region, the vias are arranged in the first direction to form via rows; the via rows comprise a first via row, a second via row and a third via row; along the second direction, the second via row is located between the first via row and the third via row; a number of vias in the second via row is less than a number of vias in the first via row; and the number of vias in the second via row is less than a number of vias in the third via row.

14. The display panel according to claim 10, wherein
the signal bus comprises a first signal bus and a second signal bus, and a width of the first signal bus is greater than a width of the second signal bus;
a first region of the first signal bus comprises the first via, the second via, and the third via, and/or comprises the fourth via, the fifth via, and the sixth via; and
in a region of the second signal bus, the vias are arranged in a via array having a rows and b columns, where a and b are integers, a≥2, and b≥2.

15. The display panel according to claim 14, wherein
the first signal bus comprises a data bus, and the second signal bus comprises a switch control line; and
the display panel comprises a short-circuiting bar and a first data line extending along the second direction, the short-circuiting bar is arranged between adjacent pixel circuit rows, the short-circuiting bar has a control end connected to the switch control line, a first end connected to the data bus, and a second end connected to the first data line.

16. The display panel according to claim 1, wherein
the signal bus comprises a data bus and a switch control line;
the display panel comprises a short-circuiting bar and a first data line extending along the second direction, the short-circuiting bar is arranged between adjacent pixel circuit rows, the short-circuiting bar has a control end connected to the switch control line, a first end connected to the data bus, and a second end connected to the first data line; and
the data bus and the switch control line that are connected to a same short-circuiting bar are arranged between two adjacent pixel circuit rows.

17. The display panel according to claim 16, wherein
the short-circuiting bar comprises a source electrode, and the source electrode and the first line segment are arranged in a same layer and are formed as an integrated structure.

18. The display panel according to claim 16, wherein
the display panel comprises a light-emitting device;
the plurality of pixel circuits comprise a first driving circuit configured to control a duration of providing a driving current to the light-emitting device based on a first data voltage, and a second driving circuit configured to control an amplitude of providing the driving current to the light-emitting device based on a second data voltage; and
the first data line is configured to provide the first data voltage.

19. The display panel according to claim 1, further comprising:
a first end extending along the second direction, wherein the signal bus extends to an edge of the first end.

20. A display device, comprising a display panel, wherein the display panel comprises:
a substrate;
a plurality of pixel circuits, wherein the plurality of pixel circuits are provided in a first direction to form a plurality of pixel circuit rows, and the plurality of pixel circuit rows are arranged in a second direction;
a plurality of signal terminals provided at a side of the plurality of pixel circuit rows in the second direction;
a signal bus extending in the first direction and arranged between two adjacent pixel circuit rows; and
a connection line segment extending in the second direction,
wherein the plurality of pixel circuits, the plurality of signal terminals, the signal bus, and the connection line segment are arranged at a side of the substrate, and the first direction intersects with the second direction;
wherein a first end of the connection line segment is electrically connected to the signal bus, and a second end of the connection line segment is electrically connected to at least one of the plurality of signal terminals; and
wherein the signal bus comprises a first line segment and a second line segment, and the first line segment and the second line segment are arranged in the first direction and in different layers.
